(19) United States
(12) Patent Application Publication
(10) Pub. No.: US 2025/0118703 A1
(43) Pub. Date: Apr. 10, 2025

(54) METHOD OF MANUFACTURING SEMICONDUCTOR DEVICES AND CORRESPONDING DEVICE

(71) Applicant: STMicroelectronics International N.V., Geneva (CH)

(72) Inventors: Claudio ZAFFERONI, Milano (IT); Antonio BELLIZZI, Cologno Monzese (IT); Alessandro MELLINA GOTTARDO, Milano (IT)

(73) Assignee: STMicroelectronics International N.V., Geneva (CH)

(21) Appl. No.: 18/904,478

(22) Filed: Oct. 2, 2024

(30) Foreign Application Priority Data
Oct. 4, 2023 (IT) 102023000020505

(51) Int. Cl. H01L 23/00

(52) U.S. Cl. CPC H01L 24/84; H01L 2224/84007; H01L 2224/8403

(57) ABSTRACT

A semiconductor chip is covered by a non-LDS encapsulation material (i.e., encapsulation material not including LDS-activatable additives). One or more first pathways are opened towards the semiconductor chip through the non-LDS encapsulation material. LDS encapsulation material (i.e., encapsulation material including LDS-activatable additives) is molded over the non-LDS encapsulation material to fill the first pathways. One or more second pathways, aligned with the first pathways, are opened towards the semiconductor chip through the LDS encapsulation material. The second pathways have an inner lining of LDS encapsulation material. Electrical coupling formations for the semiconductor chip are provided via laser direct structuring processing of the LDS encapsulation material including the inner lining in the second pathways.

### PRIORITY CLAIM

This application claims the priority benefit of Italian Application for Patent No. 102023000020505, filed on Oct. 4, 2023, the content of which is hereby incorporated by reference in its entirety to the maximum extent allowable by law.

### TECHNICAL FIELD

The description relates to manufacturing semiconductor devices.

One or more embodiments can be applied, for instance, to micro electro-mechanical systems (MEMS) thermo-generators comprising a fragile suspended membrane over a sealed cavity.

### BACKGROUND

United States Patent Application Publication Nos. 2021/0305191 and 2023/0035470, incorporated herein by reference, are exemplary of possible applications of Laser Direct Structuring (LDS) technology in manufacturing integrated circuit (IC) semiconductor devices.

Laser Direct Structuring (LDS), oftentimes referred to also as Direct Copper Interconnect (DCI), is a technology based on the structuring of a plastic material by a laser source. The lasered traces are then plated with a conductive material in order to provide a conductive patterning.

Laser Induced Strip Interconnection (LISI) is another designation sometimes applied to that technology.

In the LISIPACK™ family of products by STMicroelectronics, an LDS molding compound is used to cover (encapsulate) a die and electrically conductive lines (vias, traces) are “structured” in the LDS molding compound.

In certain specific applications, a non-LDS coating layer (tape, mold film, thick passivation, and so on) may already be present that is intrinsically non-compatible with an LDS process flow in so far as that layer does not contain any LDS additive.

There is a need in the art to contribute in addressing the issues above.

### SUMMARY

One or more embodiments relate to a method.

One or more embodiments relate to a corresponding (integrated circuit, IC) semiconductor device.

In an embodiment, a method comprises: opening vias (pathways)—via laser drilling, for instance—in a first non-LDS layer towards a metal (copper, for instance) pad in a die; filling the opened vias (pathways) in the non-LDS layer with an LDS molding compound (thus also closing the die package); re-opening the vias (pathways) opened during the first step and then filled with the LDS molding compound so that they are lined with LDS material; and applying standard LDS (LISIPACK™, for instance) processing to the LDS material to provide connection formations such as vias on lead and traces.

The solutions described herein can be advantageously applied, for instance, to micro electro-mechanical systems (MEMS) thermo-generators comprising a fragile suspended membrane over a sealed cavity.

### BRIEF DESCRIPTION OF THE DRAWINGS

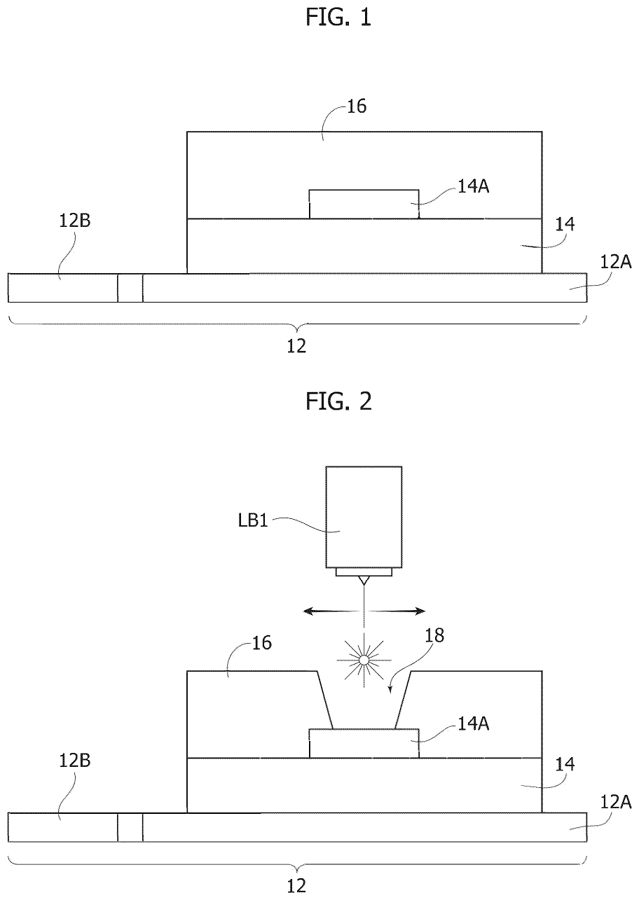

One or more embodiments will now be described, by way of example only, with reference to the annexed figures, wherein FIGS. 1 to 5 are exemplary of a possible sequence of steps in a process of manufacturing an (integrated circuit, IC) semiconductor device.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale. The edges of features drawn in the figures do not necessarily indicate the termination of the extent of the feature.

In the ensuing description, various specific details are illustrated in order to provide an in-depth understanding of various examples of embodiments according to the description. The embodiments may be obtained without one or more of the specific details, or with other methods, components, materials, etc. In other cases, known structures, materials, or operations are not illustrated or described in detail so that various aspects of the embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment”, “in one embodiment”, or the like, that may be present in various points of the present description do not necessarily refer exactly to one and the same embodiment. Furthermore, particular configurations, structures, or characteristics may be combined in any adequate way in one or more embodiments.

The headings/references used herein are provided merely for convenience and hence do not define the extent of protection or the scope of the embodiments.

In recent times, Laser Direct Structuring (LDS), oftentimes referred to also as Direct Copper Interconnect (DCI), has added to the conventional scenario of providing interconnections in integrated circuit (IC) semiconductor devices as exemplified by documents such as U.S. Pat. Nos. 9,171,739 and 10,796,981 or United States Patent Application Publication No. 2016/0324009, all incorporated herein by reference.

As discussed in the introductory portion of this description, LDS is a technology based on the structuring of a plastic material by a laser source.

LDS is now widely used in various sectors of the industrial and consumer electronics markets, for instance for high-performance antenna integration, where an antenna design can be directly formed onto a molded plastic part.

In an exemplary process, the molded parts can be produced with commercially available insulating resins that include additives suitable for the LDS process; a broad range of resins such as polymer resins like PC, PC/ABS, ABS, LCP and LDS additives such as copper-based, copper-chromite seed-forming additives are currently available for that purpose.

A laser beam can be used to transfer (“structure” or “activate”) a desired electrically conductive pattern onto an LDS molding compound that may then be subjected to metallization to finalize a desired conductive pattern.

Metallization may involve electroless plating followed by electrolytic plating. Electroless plating, also known as chemical plating, is a class of industrial chemical processes that creates metal coatings on various materials by autocatalytic chemical reduction of metal cations in a liquid bath. In electrolytic plating, an electric field between an anode and a workpiece, acting as a cathode, forces positively charged metal ions to move to the cathode where they give up their charge and deposit themselves as metal on the surface of the workpiece.

LDS can be applied to IC package families where conventional wire bonding is replaced with copper plated vias and lines (traces).

Reference is made to United States Patent Application Publication Nos. 2021/0305191, 2023/0035470, 2018/0342453, 2019/0115287, 2020/0203264, 2020/0321274, 2021/0050226, 2021/0050299, 2021/0183748, or 2021/0305203 A1 (all incorporated herein by reference) which are exemplary of the possibility of applying LDS technology in manufacturing semiconductor devices.

For instance, LDS technology facilitates replacing wires, clips or ribbons with lines/vias created by laser beam processing of an LDS material followed by metallization (growing metal such as copper via a plating process, for instance).

Electrically conductive coupling can be provided in the LDS material (once consolidated, via thermosetting, for instance): as through mold vias (TMVs) that extend through an LDS encapsulation between a top (front) surface of the LDS encapsulation and electrically-conductive pads at the front or top surface of a chip or die and/or corresponding leads in a leadframe; and as electrically-conductive lines or traces that extend at the front or top surface of the LDS encapsulation and electrically couple through mold vias to provide a desired electrical connection (routing) pattern.

Electrical components (passive components such as resistors, for instance) may be possibly arranged along one or more of the lines or traces.

Providing such electrically conductive formations using LDS material thus essentially involves: structuring these formations in the LDS material at the desired locations (by laser drilling, for instance); and growing electrically conductive material (a metal such as copper, for instance) at the locations previously structured (activated).

The related back-end manufacturing may thus involve a combination of laser machining, molding and plating process steps in a dedicated combination, with an LDS molding compound used to cover and encapsulate a die.

Certain specific applications may involve a particular non-LDS coating layer, tape, mold film, thick passivation and so on, which is already present on the semiconductor chip or die: this may be, for instance, the case of micro electro-mechanical systems (MEMS) thermo-generators comprising a fragile suspended membrane over a sealed cavity.

In these applications, a protective layer may be already present as a thin layer of protective material that does not contain LDS additives that can be laser-activated and, consequently, cannot be plated with metal (copper, for instance) after laser drilling as specified in a conventional LDS process flow.

That is, these applications seem intrinsically not compatible with LDS processing in so far as the encapsulation layer does not contain any LDS additive that can be activated (structured) and plated with electrically conductive material such as copper.

Solutions as described herein facilitate applying LDS processing also to these applications by “converting” a product otherwise not compatible with LDS processing into a product to which LDS processing can be applied.

This may involve a double drilling approach to integrate a non-LDS layer into an LDS process (LISIPACK™, for instance) using an “adhesive” metal (Cu, for instance) deposition.

In solutions as described herein, a (continuous) patch can be provided between a leadframe and a die pad which can be (copper) plated by forming in a first non-LDS protective layer one or more openings that are filled with LDS molding compound wherein “plateable” vias are formed.

FIGS. 1 to 5 are exemplary of a possible sequence of steps in a process of manufacturing an (integrated circuit, IC) semiconductor device.

The sequence of steps of FIGS. 1 to 5 is otherwise merely exemplary in so far as: one or more steps illustrated in FIGS. 1 to 5 can be omitted, performed in a different manner (with other tools, for instance) and/or replaced by other steps; and/or additional steps may be added.

The exemplary sequence of steps of FIGS. 1 to 5 is shown in connection with manufacture of an integrated circuit (IC) semiconductor device 10 comprising a leadframe 12 having one or more (integrated circuit) chips or dice 14 attached on one or more die pads 12A in the lead frame 12, with electrically conductive leads 12B around the die pad 12A having the die/dice 14 mounted thereon with a metal (copper, for instance) pad 14A provided at the front or top surface of the chip 14.

The designation lead frame (or leadframe) is currently used (see, for instance the USPC Consolidated Glossary of the United States Patent and Trademark Office) to indicate a metal frame which provides support (here at 12A) for a semiconductor chip or die (here 14) as well as electrical leads (here 12B) to couple the semiconductor chip or die to other electrical components or contacts.

Essentially, a leadframe comprises an array of electrically conductive formations (such as the leads 12B) which from a peripheral location extend inwardly in the direction of the semiconductor chip or die 14, thus forming an array of electrically conductive formations from the die pad 12A configured to have at least one semiconductor chip or die attached thereon. This may be via a die attach adhesive (a die attach film (DAF), for instance).

A single chip or die 14 mounted on a single die pad 12A and a single lead 12B are shown in the drawings for simplicity; as used herein, the words chip(s) and die/dice are regarded as synonyms.

As a starting point of the exemplary sequence of FIGS. 1 to 5 an “intermediate” product is considered that, in response to (otherwise conventional) manufacturing steps, already includes a die 14 mounted on a die pad 12A in a leadframe 12 with a protective encapsulation 16 (already) molded thereon.

As illustrated, the chip 14 includes an electrically conductive pad 14A at its front or top surface.

The encapsulation 16 includes a non-LDS coating layer, tape, mold film, thick passivation and so on, which is already present on the semiconductor chip or die.

Such a non-LDS encapsulation material 16 (an epoxy resin, for instance) is easily identifiable, and thus distinguishable from an LDS encapsulation material, as it is essentially exempt from LDS additives, such as copper-based, copper-chromite seed-forming additives, for instance.

More generally, such a non-LDS encapsulation material is easily recognizable as, due to the absence (or poor contents) of LDS activatable additives, it cannot be activated (structured) and plated with metal such as copper.

The encapsulation 16 of non-LDS material that covers the chip or die 14, 14A may be (already) provided for various reasons that are of no specific concern for the discussion herein. By way of example, this may be the case of micro electro-mechanical systems (MEMS) thermo-generators comprising a fragile suspended membrane over a sealed cavity.

The (otherwise conventional) structure of the product illustrated in FIG. 1 is thus exemplary of applications where a (first) encapsulation 16 may be already present (as a thin layer of protective material) that does not contain LDS additives and, consequently, cannot be plated with metal (copper, for instance) after laser drilling as specified in a conventional LDS process flow.

FIG. 2 is exemplary of a first drilling step performed on the product illustrated in FIG. 1.

The purpose of this first drilling step (which can be performed via laser beam energy LB1 as otherwise conventional in the art) is to open (“drill”) the non-LDS encapsulation layer 16 and form therein one or more (first) pathways 18 (also referred to as “openings” for simplicity) 18 that extend from a front surface of the encapsulation 16 (opposite the leadframe 12) towards the front or top surface of the chip 14 (that is, towards the pad 14A, in the example illustrated here).

The drilling step of FIG. 2 thus leads to “opening” the protective layer 16 by forming therein one or more openings 18 (a single opening, essentially a hole, is shown for simplicity and ease of explanation).

Advantageously, these first pathways 18 are opened through the non-LDS encapsulation 16 to an extent as close as possible to the total real metal pad area on the chip 14 (as represented here by the pad 14A).

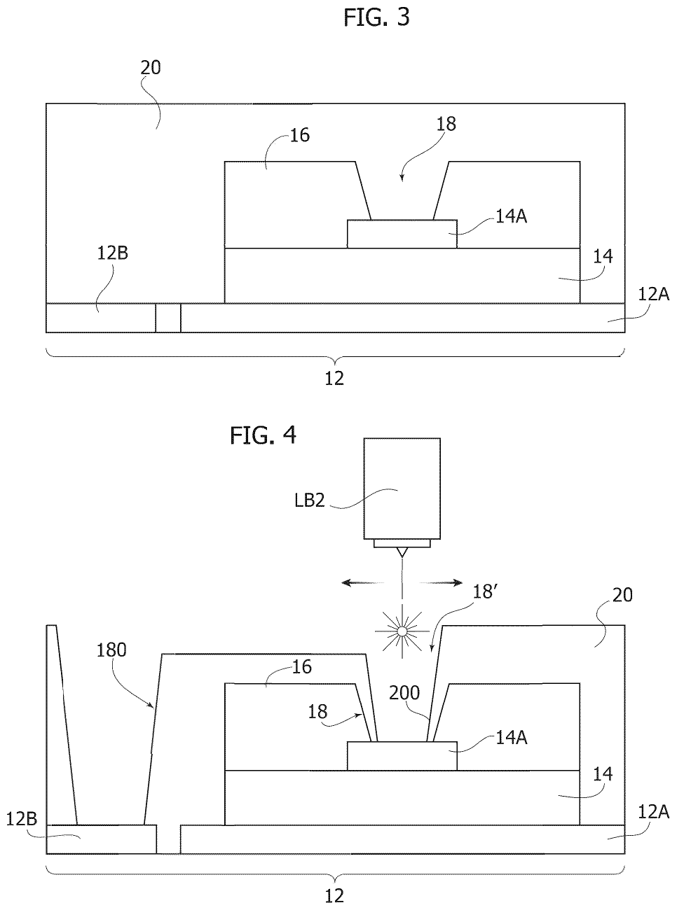

FIG. 3 is exemplary of a (second) encapsulation 20 of LDS material (of any type known to those of skill in the art) molded on the assembly of FIG. 2.

The encapsulation 20 being of LDS material means that, contrary to the non-LDS encapsulation 16, the encapsulation 20 does contain LDS activatable additives (copper-based, copper-chromite seed-forming additives, can again be referred to by way of example).

Due to the presence of LDS activatable additives, the LDS encapsulation 20 can be activated (structured) and plated with metal such as copper after laser drilling as specified in a conventional LDS process flow.

The molding step of FIG. 3 (as discussed in the following, this step is performed between two drilling steps as illustrated in FIG. 2 and FIG. 4) leads to LDS molding compound 20 being filled into the openings (pathways) 18 opened in the non-LDS layer 16.

The LDS molding compound 20 (this may be molded using any molding technique known to those of skill in the art for that purpose) thus closes the package and fills the openings 18 previously opened in the non-LDS layer 16.

FIG. 4 is exemplary of a second drilling step performed on the product illustrated in FIG. 3.

The second drilling step of FIG. 4 has the purpose of (partially) re-opening the same pathways 18 that were opened (in the non-LDS layer 16) during the step of FIG. 2 where LDS material 20 (suited for plating within the framework of LDS processing) was subsequently filled in during the molding step of FIG. 3. This second drilling step forms a (second) pathway 18′ (also referred to as an “opening” for simplicity) through the LDS material 20.

The wording “partially” applied to second drilling step of FIG. 4 highlights the facts that the openings 18′ that are (re)opened in the LDS material 20 during the second drilling step of FIG. 4 are narrower (radially smaller) than the openings 18 formed in the non-LDS material 16 during the first drilling step of FIG. 2.

In that way, the openings 18′ (re)opened during the second drilling step of FIG. 4 have their inner wall lined (as indicated by the reference numeral 200) with LDS material 20 (containing LDS additives) molded during the molding step of FIG. 3.

To summarize, in a method as described herein:
one or more pathways 18 towards the semiconductor chip or chips 14, 14A are opened (via laser beam LB1, for instance) in the non-LDS encapsulation material 16: the exemplary semiconductor chip illustrated in the figures includes an electrically conductive front pad 14A covered (encapsulated) by the non-LDS encapsulation material 16. As visible in FIG. 2, for instance, the pathways 18 are opened (via laser beam drilling LB1, for instance) towards—and down to—the electrically conductive front pad 14A;
LDS encapsulation material 20 (that is material including LDS-activatable additives) is molded onto the semiconductor chip(s) 14, 14A covered by the non-LDS encapsulation material 16 having the pathway(s) 18 towards the semiconductor chip 14, 14A opened therein. In that way, as illustrated in FIG. 3, LDS encapsulation material 20 including LDS-activatable additives is filled into the pathway(s) 18 towards the semiconductor chip 14, 14B; and
the pathway(s) 18 towards the semiconductor chip 14, 14A having the LDS encapsulation material (20) filled therein, are partially re-opened (via laser beam LB2, for instance: see the pathways indicated as 18′ in FIG. 4) and thus exhibit an inner lining 200 of LDS encapsulation material.

Stated otherwise, re-opening the pathway(s) towards the semiconductor chip 14, 14A having the LDS encapsulation material 20 filled therein involves forming in such LDS encapsulation material 20 opening(s) 18′ that is/are narrower (with smaller diametral size/cross-section) than the pathway(s) 18 opened (as illustrated in FIG. 2) in the non-LDS material 16.
Advantageously, the further drilling step of FIG. 4 can be performed, like the drilling step of FIG. 2, via laser beam energy LB2 as otherwise conventional in the art.

At least in principle, the first “opening” step of FIG. 2 could be performed via other means, with pathways formed with processes other than laser drilling: etching, for instance, is exemplary of those other processes. The first opening of the non-LDS material can be achieved with different techniques since in this case no activation is needed.

The second “opening” of FIG. 4 being performed by laser drilling is advantageous since this also activates the LDS layer in the first opening (“well”): in the case of the step of FIG. 4, laser beam drilling to re-open the pathways 18′ is thus advantageous in so far as laser beam energy LB2 can serve the purpose of re-opening (“re-drilling”) the pathways 18′ while concurrently activating the LDS material of the lining 200 without distinct laser processing being required for activating the LDS additives in the LDS material.

While different reference symbols (namely LB1 and LB2) are used in FIG. 2 and FIG. 4, the laser beam source used in the step of FIG. 4 may be the same laser beam source used for the step of FIG. 2.

This represents an advantageous option in so far as a same alignment of a same laser source with respect to the chip 14/pad 16 can be adopted with a different focus adjustment (drilling size).

Even if the first drilling step is performed on a non-molded leadframe and the second drilling step is on a molded leadframe, the alignment fiducials can be the same in both instances. For instance, they may be “ovals” on the edge of the leadframes in a region not reached by the molding compound.

Laser beam energy can be provided with a first beam LB1 during opening the pathway(s) 18 in the non-LDS encapsulation material 16 and with a second beam LB2 during re-opening the pathway(s) 18′ having the LDS encapsulation material 20 filled therein. Advantageously, the second beam LB2 is narrower than the first beam LB1 so that the re-opened pathway(s) 18′ is/are narrower than the pathway(s) 18 opened in the non-LDS encapsulation material 16 to form the lining 200.

The lining of LDS material 200 “activated” (by the laser beam LB2 during drilling in the second drilling step of FIG. 4, for instance) can be processed (plated via electroless/electrolytic plating, for instance) as in a standard LDS process flow.

The combination of the two steps of FIGS. 2 and 4 (with the molding step of FIG. 3 between them) thus facilitates “reclaiming” for LDS processing a product like the one illustrated in FIG. 1, which would otherwise look unsuitable for LDS processing.

The combination of the two steps of FIG. 2 and FIG. 4 (with the molding step of FIG. 3 between them) facilitates providing electrical coupling for a semiconductor chip 14, 14A via laser direct structuring, LDS processing of LDS encapsulation material (that is, encapsulation material including LDS-activatable additives) in case where the semiconductor chip is (already) covered by non-LDS encapsulation material (that is, encapsulation material substantially exempt from LDS-activatable additives that is unsuited to be plated).

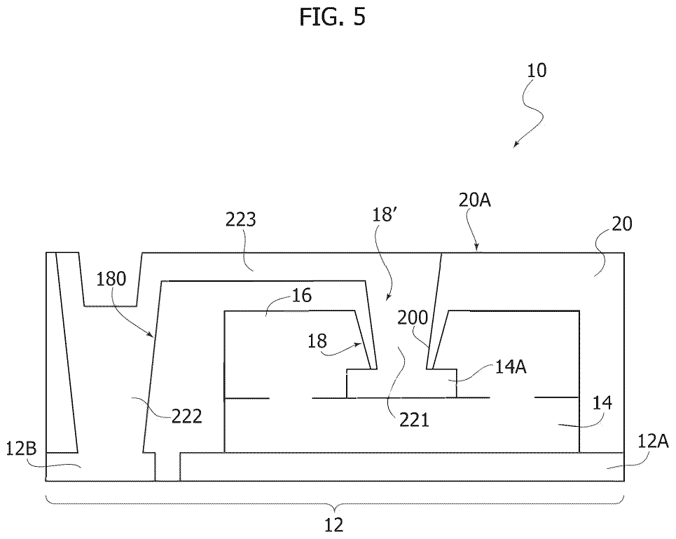

For instance (as exemplified in FIG. 5) electrically conductive formations can be provided to electrically couple the semiconductor chip(s) 14 to selected ones of the leads (outer pads) 12B in the leadframe 12.

As illustrated in FIG. 5, electrical coupling formations 221, 222, 223 for the semiconductor chip 14, 14A can be produced via laser direct structuring, LDS processing the LDS encapsulation material 20. This includes applying LDS processing to the inner lining 200 of the re-opened pathway(s) 18′.

As illustrated in FIG. 5, these coupling formations may comprise:
first through mold vias (TMVs) 221 comprising conductive material such as copper grown into the re-opened pathway or pathways 18′ extending between the top (front) surface 20A of the LDS encapsulation 20 and the electrically-conductive pad 14A at the front or top surface of the chip or die 14;
second through mold vias (TMVs) 222 comprising conductive material grown into (further) pathways 180 that can be formed concurrently with the step of FIG. 4 to extend between the top (front) surface 20A of the LDS encapsulation 20 and corresponding leads 12B in the leadframe 12; and electrically conductive lines or traces 223 comprising conductive material grown at the front or top surface 20A of the LDS encapsulation 20 and electrically couple selected ones of the first vias 221 with selected ones of the second vias 222 to provide a desired electrical connection (routing) pattern between the chip or die 14 and the leads 12B.

Providing the electrically conductive formations 221, 222, 223 essentially involves: structuring these formations in the LDS material 20 (including structuring the LDS “lining” 200 of the pathways 18′ partially re-opened via laser beam energy as exemplified in FIG. 4), and growing electrically conductive material (a metal such as copper, for instance) at the locations previously activated (structured).

For instance, an electrical coupling formation such as the through mold via, TMV 221 for the semiconductor chip 14, 14A can be formed by: laser activating (see reference LB2 in FIG. 4) the LDS encapsulation material in the inner lining 200 of the re-opened pathway 18′; and growing electrically conductive material (electroless plus electrolytic copper, for instance) in the re-opened pathway 18′ having the LDS additives in the inner lining 200 of LDS encapsulation material activated (structured) by laser bean energy.

The related LDS processing may be along the lines of the solutions exemplified in the patent reference documents cited at the outset of the present description.

Without prejudice to the underlying principles, the details and embodiments may vary, even significantly, with respect to what has been described in the foregoing, by way of example only, without departing from the extent of protection.

The claims are an integral part of the technical teaching on the embodiments as provided herein.

The extent of protection is determined by the annexed claims.

1. A method, comprising:
providing a semiconductor chip which is covered by a first encapsulation material;
wherein said first encapsulation material does not include Laser Direct Structuring (LDS) additives;
opening a first pathway through the first encapsulation material to reach a conductive structure;
molding a second encapsulation material over the first encapsulation material and filling the first pathway;
wherein the second encapsulation material does include LDS additives;
opening a second pathway, aligned with the first pathway, through the second encapsulation material to reach the conductive structure;
wherein second pathway has an inner lining made of the second encapsulation material; and
providing electrical coupling to the conductive structure via laser direct structuring processing the second encapsulation material including said inner lining of the second pathway.

2. The method of claim 1, wherein opening the second pathway comprises applying laser beam energy, and wherein the inner lining is laser structured by said laser beam energy.

3. The method of claim 1, wherein the second pathway is narrower than the first pathway.

4. The method of claim 1, wherein opening the first pathway comprises applying laser beam energy, and wherein opening the second pathway comprises applying laser beam energy.

5. The method of claim 4, wherein the inner lining is laser structured by said laser beam energy.

6. The method of claim 4, wherein applying laser beam energy for opening the first pathway comprises using a first laser beam, and wherein applying laser beam energy for opening the second pathway comprises using a second laser beam, and wherein the second laser beam is narrower than the first laser beam.

7. The method of claim 6, wherein the first laser beam and the second laser beam have a same alignment and different focus adjustments.

8. The method of claim 1, wherein the conductive structure is a conductive pad on the semiconductor chip.

9. The method of claim 1, wherein the second encapsulation material covers a leadframe to which the semiconductor chip is mounted, the method further comprising:
opening a third pathway through the second encapsulation material to reach the leadframe; and
providing electrical coupling to the leadframe via laser direct structuring processing the second encapsulation material.

10. The method of claim 1, wherein providing electrical coupling for the semiconductor chip comprises:
laser activating the second encapsulation material in the inner lining of the second pathway; and
growing electrically conductive material in the second pathway with said laser activated inner lining of second encapsulation material forming therein an electrical coupling formation for the semiconductor chip.

11. A device, comprising:
a semiconductor chip;
a first encapsulation material covering the semiconductor chip;
wherein said first encapsulation material does not include Laser Direct Structuring (LDS) additives;
a first pathway in the first encapsulation material extending towards the semiconductor chip;
a second encapsulation material molded over the first encapsulation material and present within the first pathway;
wherein the second encapsulation material does include LDS additives;
a second pathway, aligned with the first pathway, extending through the second encapsulation material;
wherein second pathway has an inner lining made of the second encapsulation material; and
electrical coupling for the semiconductor chip provided via laser direct structured electrically conductive structures at the inner lining of the second pathway.

12. The device of claim 11, wherein the semiconductor chip includes an electrically conductive front pad covered by the first encapsulation material, wherein the first pathway extends towards the semiconductor chip and reaches said electrically conductive front pad, and wherein the second pathway extends towards the semiconductor chip and reaches said electrically conductive front pad.

13. The device of claim 11, further comprising:
a leadframe to which the semiconductor chip is mounted;
wherein the second encapsulation material covers the leadframe;
a third pathway extending through the second encapsulation material to the leadframe; and
electrical coupling for the leadframe provided via laser direct structured electrically conductive structures at the third pathway.

14. The device of claim 11, wherein the electrical coupling for the semiconductor chip comprises:
laser activated second encapsulation material in the inner lining of the second pathway; and
electrically conductive material grown in the second pathway at said laser activated second encapsulation material.
